(19) United States
(12) Patent Application Publication
(10) Pub. No.: US 2007/0063188 A1
(43) Pub. Date: Mar. 22, 2007

(54) Low-k dielectric material

(76) Inventors: Juha T. Rantala, Espoo (FI); Jyri Paulasaari, Turku (FI); Jarkko Pietikainen, Helsinki (FI); Teemu Tormanen, Espoo (FI); Nigel Hacker, Espoo (FI); Nungavaram Viswanathan, San Jose, CA (US)

Correspondence Address: KUBOVCIK & KUBOVCIK, SUITE 710, 900 17TH STREET NW, WASHINGTON, DC, 20006, US

(21) Appl. No.: 10/552,737

(22) PCT Filed: Apr. 13, 2004
(86) PCT No.: PCT/FI04/00224

§ 371 Date: Sep. 26, 2006

(30) Foreign Application Priority Data
Apr. 11, 2003 (US) 60461820

(51) Int. Cl. H01L 51/00; C07F 7/12

(52) U.S. Cl. 257/40; 257/E51.02; 556/488; 438/1

(57) ABSTRACT

The present invention relates to thin films suitable as dielectrics in integrated circuits and for other similar applications and to methods for the production thereof. In particular, the invention concerns thin films comprising at least partially cross-linked siloxane structures obtainable by hydrolysis of one or more silicon compounds of the general formula R₁—R₂—Si—(X₁)₃, wherein X₁ is a leaving group, R₂ is a cycloalkyl having from 3 to 16 carbon atoms, an aryl having from 5 to 18 carbon atoms or a polycyclic alkyl group having from 7 to 16 carbon atoms, and R₁ is a substituent of R₂ selected from alkyl groups having from 1 to 4 carbon atoms, alkenyl groups having from 2 to 5 carbon atoms, alkynyl groups having from 2 to 5 carbon atoms, and aromatic groups having 5 or 6 carbon atoms, each of said groups being optionally substituted, and Cl and F.

### BACKGROUND OF THE INVENTION

1. Field of the Invention

The present invention relates to thin films suitable as dielectrics in IC's and for other similar applications. In particular, the invention concerns thin films comprising compositions obtainable by hydrolysis of one or more silicon compounds, which yield an at least partially cross-linked siloxane structure. The invention also concerns a method for producing such films by preparing siloxane compositions by hydrolysis of suitable reactants, by applying the hydrolyzed compositions on a substrate in the form of a thin layer and by curing the layer to form a film.

2. Description of Related Art

Built on a semiconducting substrate, integrated circuits comprise of millions of transistors and other devices, which communicate electrically with one another and outside packaging material through multiple levels of vertical and horizontal wiring embedded in a dielectric material. Within the multilayer metallization structure, “vias” comprise the vertical wiring, whereas “interconnects” comprise the horizontal wiring. Fabricating the metallization can involve the successive depositing and patterning of multiple layers of dielectric and metal to achieve electrical connection among transistors and to outside packaging material. The patterning for a given layer is often performed by a multi-step process consisting of layer deposition, photoresist spin, photoresist exposure, photoresist develop, layer etch, and photoresist removal on a substrate. Alternatively, the metal may sometimes be patterned by first etching patterns into a dielectric, filling the pattern with metal, then subsequently chemical mechanical polishing the metal so that the metal remains embedded only in the openings of the dielectric. As an interconnect material, aluminum has been utilized for many years due to its high conductivity (and low cost). Aluminum alloys have also been developed over the years to improve the melting point, diffusion, electromigration and other qualities as compared to pure aluminum. Spanning successive layers of aluminum, tungsten has traditionally served as the conductive via material. Silicon dioxide (dielectric constant of around 4.0) has been the dielectric of choice, used in conjunction with aluminum-based and tungsten-based interconnects and via for many years. The drive to faster microprocessors and more powerful electronic devices in recent years has resulted in very high circuit densities and faster operating speeds, which in turn have required higher conductivity metals and lower-k dielectrics (preferably below 3.0, more preferably below 2.5 dielectric constant). In the past few years, VLSI (and ULSI) processes have been moving to copper damascene processes where copper (or copper alloys) is used for the higher conductance in the conductor lines and spin-on or CVD low-k dielectrics are used for the insulating material surrounding the conductor lines. To circumvent problems with etching, copper along with a barrier metal is blanket deposited over recessed dielectric structures consisting of interconnect and via openings and subsequently polished in a processing method known as “dual damascene.” The bottom of the via opening is usually the top of an interconnect from the previous metal layer or in some instances, the contacting layer to the substrate.

FIG. 1 gives an example of a typical process for patterning a dielectric film. First, a dielectric layer film 12 is deposited on a wafer substrate 10 typically by spin-on or chemical vapor deposition processes. Next, a removable, photosensitive “photoresist” film 14 is spun onto the wafer substrate 10. Afterward, the photoresist 12 is selectively exposed through a mask, which serves as a template for the layer's circuit pattern and is subsequently developed (developer applied to remove either exposed or unexposed areas depending upon the type of resist). The photoresist is typically baked after spin, exposure, and develop. Next, the layer film is etched in a reactive plasma, wet bath, or vapor ambient in regions not covered by the photoresist to define the circuit pattern. Lastly, the photoresist 14 is stripped. The process of layer deposition, photoresist delineation, etching, and stripping is repeated many times during the fabrication process.

Because photoresist may unacceptably erode during the etch process or may not be able to be adequately delineated within device specifications, a hard mask is sometimes inserted between the layer film and the photoresist (the materials of the invention could also be used for making such a hard mask). FIG. 2 illustrates this typical method, which is similar to the dielectric patterning process described previously in relation to FIG. 1. The layer film could be metal, semiconductor, or dielectric material depending on the application. As can be seen in FIG. 2, a substrate 10 is provided on which is deposited a layer film 12. On film 12 is deposited a hard mask 13. On hard mask 13 is deposited a photoresist material 14. The photoresist is exposed and developed so as to selectively expose the underlying hard mask 13. Then, as can be further seen in FIG. 2, the hard mask 13 is etched via the exposed areas in photoresist 12. Thereafter, the photoresist is removed and the dielectric film 12 is etched by using the hard mask 13 as the pattern mask.

The “dual damascene” process used in integrated circuit application combines dielectric etches and sometimes hard masks to form trenches and vias to contain metal interconnects. FIG. 3 demonstrates one implementation of the technique. From the bottom up in FIG. 3a, the stack is made up of a substrate 20, a dielectric film 22, a hard mask 23, a second dielectric film 24, and a patterned photoresist layer 26. After etching and photoresist strip, a dual-width trench feature is formed as shown in FIG. 3b. The openings are then filled with metal and subsequently polished, leaving metal only within the openings.

The procedures shown in FIGS. 1-3 are often repeated many times during integrated circuit application, which adds to the cost of the circuit and degrades yield. Reducing the number of steps, such as implementing a photopatternable dielectric material, which obviates the need for photoresist and etching steps, has huge benefits to the circuit manufacturer.

In addition to the dielectric IC material being photopatternable, it is also desirable that the material be easy to deposit or form, preferably at a high deposition rate and at a relatively low temperature. Once deposited or formed, it is desirable that the material be easily patterned, and preferably patterned with small feature sizes if needed. Once patterned, the material should preferably have low surface and/or sidewall roughness. It might also desirable that such materials be hydrophobic to limit uptake of moisture (or other fluids), and be stable with a relatively high glass transition temperature (not degrade or otherwise physically and/or chemically change upon further processing or when in use).

In one embodiment of the present invention, hybrid organic-inorganic materials are used for IC applications. In this embodiment, the hybrid materials of the invention can provide the benefits of low dielectric constant, direct patternability, by exposure to light or particle beam, as well as other characteristics such as stability, glass transition temperature, ease of handling and deposition, etc. In this embodiment, the hybrid materials of the can have an inorganic backbone, including but not limited to one that is made of a metal or metalloid oxide three dimensional network, and the like, with organic substituents and cross linking groups, that can be partially or fully fluorinated.

Summarizing: aside from possessing a low dielectric constant, the ideal dielectric should afford the following properties:

1) A high modulus and hardness in order to bind the maze of metal interconnects and vias together as well as abet chemical mechanical polishing processing steps.

2) Low thermal expansion, typically less than or equal to that of Al interconnects.

3) Excellent thermal stability, generally in excess of 400° C.

4) No cracking, excellent fill and planarization properties

5) Excellent adhesion to dielectric, semiconductor, and metal materials.

6) Sufficient thermal conductivity to dissipate joule heating from interconnects and vias.

7) Material density that precludes absorption of solvents, moisture, or reactive gasses.

8) Allows well-defined vertical etch profiles at very small dimensions.

9) Low current leakage, high breakdown voltages, and low loss-tangents.

10) Stable interfaces between the dielectric and contacting materials.

By necessity, low-k materials are usually engineered on the basis of compromises. Silicate-based low-k materials can demonstrate exceptional thermal stability and usable modulus but can be plagued by brittleness and cracking. In contrast, organic materials often show improved material toughness, but at the expense of increased softness, lower thermal stability, and higher thermal expansion coefficients. Porous materials sacrifice mechanical properties and possess a strong propensity for absorbing chemicals used in semiconductor fabrication leading to reliability failures. Fluorinated materials can induce corrosion of metal interconnects, rendering a chip inoperative. Universally, low-k materials sacrifice mechanical robustness and thermal conductivity with respect to their pure silicon dioxide analogues, making integration into the fabrication flow very challenging.

Further, known materials comprising exclusively inorganic bonds making up the siloxane matrix are brittle and have poor elasticity at high temperatures.

### SUMMARY OF THE INVENTION

It is an object of the present invention to improve and eliminate the problems of the known technical solutions and to provide novel low dielectric constant thin films, which have excellent mechanical and thermal properties.

It is a second object of the invention to provide methods of producing poly(organo siloxane) compositions which are suitable for the preparation of thin films having low dielectric constant. Materials providing dielectric constant values of <2.7, <2.5 and <2.3 are also claimed.

It is a third object of the invention to provide a method of patterning dielectric films in semiconductor devices.

It is a fourth object of the invention to have precursor monomers, which allow the control electronic polarization of the material and furthermore tunability of dielectric constant of the thin film.

It is a fifth objective of the invention having siloxane polymer composition, which enhance removal of residual silanol groups from the thin film.

It is still a sixth object of the invention to provide novel molecules for forming of low dielectric constant material formed by a CVD (Chemical Vapor Deposition) method.

These and other objects, together with the advantages thereof over the known dielectric thin films and methods for the preparation thereof, which shall become apparent from specification which follows, are accomplished by the invention as hereinafter described and claimed.

The present invention is based on the concept of providing a poly(organo siloxane) material, which exhibits both inorganic and organic bonds within the cured and at least partially cross-linked siloxane composition to give a product which has excellent strength properties and good heat-resistance. The inorganic cross-links are based on the conventional silicon-to-oxygen bonds of a siloxane material. However, in addition to these basically inorganic and partially inflexible bonds, the novel materials may also have organic inter- and intra-chain links formed by the carbon-to-carbon bonds. These bonds are derived from the reactions of unsaturated groups, such as alkenyl or alkynyl groups, with other unsaturated groups.

More specifically, according to the present invention thin films comprising at least partially cross-linked siloxane structures are obtainable by hydrolysis of one or more silicon compounds of the general formula
R₁—R₂—Si—(X)₃,
wherein
X₁ is a leaving group,
R₂ is a cycloalkyl having from 3 to 16 carbon atoms, an aryl having from 5 to 18 carbon atoms or a polycyclic alkyl group having from 7 to 16 carbon atoms, and
R₁ is a substituent of R₂ selected from alkyl groups having from 1 to 4 carbon atoms, alkenyl groups having from 2 to 5 carbon atoms, alkynyl groups having from 2 to 5 carbon atoms, and aromatic groups having 5 or 6 carbon atoms, each of said groups being optionally substituted, and halogens, such as Cl and F.

The poly(organo siloxane) compounds provided by the invention typically comprise a repeating Si—O backbone, carbon chain cross-linking groups and —R₁—R₂ bound to from 5% to 50% of the silicon atoms in the Si—O backbone. The Si—O-backbone can further comprise R₃ groups bound to the silicon atoms in the Si—O backbone, wherein R₃ is an alkyl chain having from 1 to 4 carbon atoms, an alkenyl chain or an aryl group.

The thin films are excellent dielectric materials which can be used in integrated circuits having a layer with areas of an electrically conductive first material and an electrically insulating second material, wherein the second material is a poly(organo siloxane) compound of the above kind.

A method of making an integrated circuit comprises providing alternating areas of electrically insulating and electrically conducting materials within a layer on a semiconductor substrate, wherein the electrically insulating material comprises a poly(organo siloxane) compound comprising a repeating Si—O backbone, carbon chain crosslinking groups and —R₁—R₂ bound to from 5% to 50% of the silicon atoms in the Si—O backbone, wherein R₂ is a cyclic group, such as a cycloalkyl having from 3 to 16 carbon atoms, an aryl having from 5 to 18 carbon atoms or a polycyclic alkyl group having from 7 to 16 carbon atoms, in particular an aromatic group having 6 carbon atoms, and R₁ is a substituent, in particular at position 4 of R₂, said substituent preferably being selected from an alkyl chain having from 1 to 4 carbons, an alkenyl group having from 2 to 6 carbons or OH.

These kinds of integrated circuits can, naturally, be employed in computers.

Finally, the present invention provides a simplified method of making a chemical compound of the formula R₁—R₂—Si—(X₂)₃, wherein X₂ is a halogen, R₂ is an aromatic group having 5 to 18 carbon atoms, a cycloalkyl having from 3 to 16 carbon atoms, or a polycyclic alkyl group having from 7 to 16 carbon atoms, and R₁ is a substituent, in particular at position 4 of R₂, R₁ being selected from the group consisting of alkyl groups having from 1 to 4 carbon atoms, alkenyl groups having from 2 to 5 carbon atoms, and OH groups. The method comprises:
reacting a compound of the formula R₁—R₂—Br, wherein R₁ and R₂ have the same meaning as above, with Mg and with a compound of the formula Si—(OR₃)₄, wherein R₃ is an alkoxy group having from 1 to 3 carbon atoms, to form a compound of the formula R₁—R₂—Si—(OR₃)₃, wherein R₁, R₂ and R₃ have the same meaning as above;
reacting the thus obtained compound of the formula R₁—R₂—Si—(OR₃)₃ with a halogenating agent capable of replacing, preferably each, R₃ with a halogen substantially without affecting the rest of the compound of formula R₁—R₂—Si—(OR₃)₃ to produce a compound of the formula R₁—R₂—SiX₂, wherein R₁, R₂ and X₂ have the same meaning as above, and
recovering the thus obtained compound.

As an example of mildly halogenating (in particular “chlorinating”) agents, the combination of SO₂Cl₂ with pyridyl hydrochloride (C₅H₅N—HCl) can be mentioned.

The key differentiation of the current material compared to others is that low dielectric constant can be achieved without pore generation into the material. Instead, materials are designed based on materials with electronic and dipole polarizations sufficient to achieve low dielectric constant thin film materials, while simultaneously maintaining all mechanical and thermal requirements set by integrated circuits manufacturing processes and in general related industry. The design of the precursor molecules is based on screening made by molecular modeling methods. For example, the present invention involves the use of 6-, 8-, and 10-membered aromatic and non-aromatic ring structures to obtain the desired properties. Use of mono- and polycyclic ring structures (including bridged structures) are also disclosed. Saturated and unsaturated molecules are also covered.

Next, the invention will be discussed in more detail.

### BRIEF DESCRIPTION OF THE DRAWINGS

FIG. 1 is a cross-sectional view of a conventional process flow for patterning of dielectric film using conventional processes;

FIG. 2 is a cross-sectional view of a conventional process flow for etching of a layer film through a hard mask. In some processes, the photoresist strip may occur after the film etch;

FIG. 3 is an illustration of a damascene structure before (a) and after (b) final etch and photoresist strip;

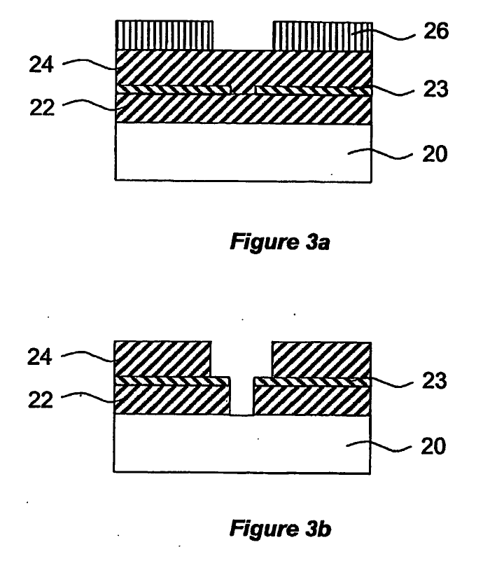

FIG. 4 is an illustration of a cross-sectional process flow of the present invention for patterning FHOSM films. Note the reduction in steps compared to the standard dielectric process depicted in FIG. 1;

FIG. 5 is a process flow of the present invention for implementing a photopatternable hard mask process using FHOSM. Note the reduction in steps compared to the convention process shown in FIG. 2; and

FIG. 6 is a “dual damascene” process flow of the present invention using FHOSM.

### DETAILED DESCRIPTION OF THE INVENTION

The various definitions used below have the following general meanings—the more specific, typical for the preferred embodiments, are given below in connection with the formulas:

‘Alkenyl’ as used herein includes straight-chained and branched alkenyl groups, such as vinyl and allyl groups. The term ‘alkynyl’ as used herein includes straight-chained and branched alkynyl groups, suitably acetylene. ‘Aryl’ means a mono-, bi-, or more cyclic aromatic carbocyclic group, substituted or non-substituted; examples of aryl are phenyl and naphthyl. More specifically, the alkyl, alkenyl or alkyl may be linear or branched. Alkyl contains preferably 1 to 18, more preferably 1 to 14 and particularly preferred 1 to 12 carbon atoms. The alkyl is preferably branched at the alpha or beta position with one and more, preferably two, C1 to C6 alkyl groups, especially preferred per-fluorinated alkyl, alkenyl or alkynyl groups. Some examples are non-fluorinated, partially fluorinated and per-fluorinated i-propyl, t-butyl, but-2-yl, 2-methylbut-2-yl, and 1,2-dimethylbut-2-yl. Alkenyl contains preferably 2 to 18, more preferably 2 to 14 and particularly preferred 2 to 12 carbon atoms. The ethylenic, i.e. two carbon atoms bonded with double bond, group is preferably located at the position 2 or higher, related to the Si or M atom in the molecule. Branched alkenyl is preferably branched at the alpha or beta position with one and more, preferably two, C1 to C6 alkyl, alkenyl or alkynyl groups, particularly preferred per-fluorinated alkyl, alkenyl or alkynyl groups.

Alkynyl contains preferably 3 to 18, more preferably 3 to 14 and particularly preferred 3 to 12 carbon atoms. The ethylinic group, i.e. two carbon atoms bonded with triple bond, group is preferably located at the position 2 or higher, related to the Si or M atom in the molecule. Branched alkynyl is preferably branched at the alpha or beta position with one and more, preferably two, C1 to C6 alkyl, alkenyl or alkynyl groups, particularly preferred per-fluorinated alkyl, alkenyl or alkynyl groups.

In the context of the disclosure the organic group substituent halogen may also be F, Cl, Br or I atom and is preferably F or Cl. Generally, term ‘halogen’ herein means a fluorine, chlorine, bromine or iodine atom.

By “polycyclic alkyl moiety” we mean, for example, an adamantyl group or a similar cage compound, which is attached to silicon by (at least one) covalent bond. Thus, for example, if each silicon atom in the deposition polymer matrix contains one relative large organic group, in case of adamantyl, the atomic ratio of carbon to oxygen is increased. Thus, a conventional siloxane polymer contains significantly more permanent dipoles than a siloxane polymer made of adamantyl containing precursors. This difference in the content of permanent dipoles affects orientational polarizability so that the orientational dielectric constant can be as low as 0.3 to 0.2 for the siloxane materials made of adamantyl substituted precursors whereas an orientational dielectric constant for conventional siloxane low-k material is typically 0.7 or higher. The adamantyl, which optionally can be substituted, as shown in the examples below, provides excellent properties for the hybrid materials.

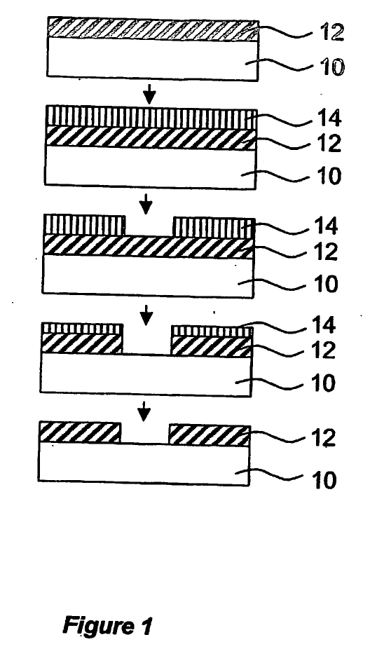

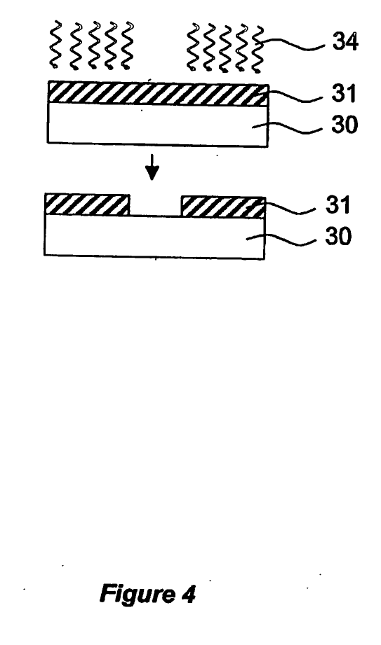

Turning now to the drawings, we note that in one embodiment of the invention, the photosensitivity of FHOSM is utilized to reduce the number of processing steps. Instead of patterning the film with photoresist and etch processes, the film dielectric itself is photopatternable like photoresist. Compared to the standard process depicted in FIG. 1, the photopatternable FHOSM process eliminates several processing steps potentially reducing costs and improving yield. As can be seen in FIG. 4, in the present invention, a substrate 30 is provided. The substrate 30 can be any suitable substrate, such as a silicon substrate, or a substrate having multiple film layers already deposited thereon. On the substrate is deposited the hybrid material 31 of the present invention. The hybrid material is selectively exposed to electromagnetic energy (e.g., UV light) or particle beam (e.g., electron beam), so as to selectively crosslink exposed areas. Non-exposed areas are removed with a developer, as can be seen in FIG. 4. Similar to photoresist, the material is baked after spin, development, and when applicable, exposure to optimize performance. As can be seen from the above, the additional steps of adding photoresist, developing the photoresist, etching through exposed areas of the photoresist, and final photoresist removal, are not needed in the present invention as compared to the prior art method illustrated in FIG. 1.

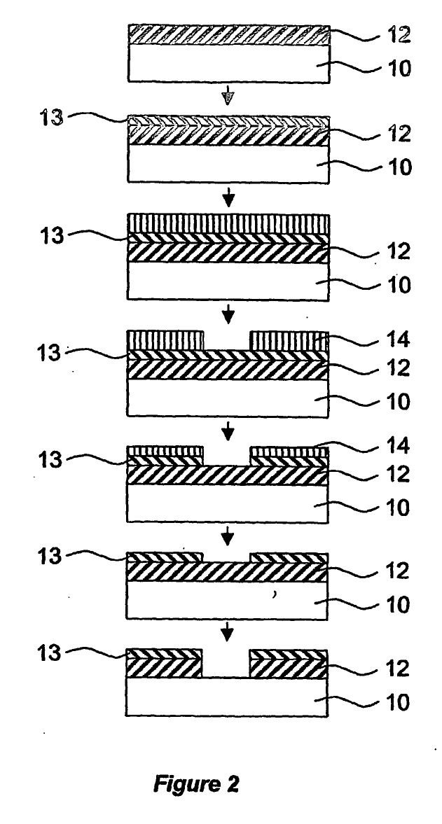

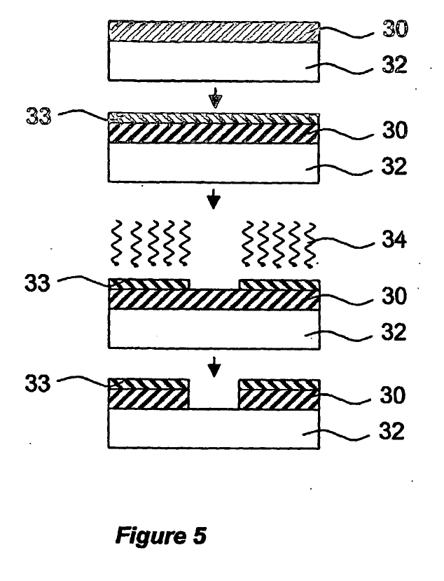

Similar to the photopatternable dielectric concept described in the previous embodiment, a photopatternable hybrid material of the present invention may be used as a hard mask material when etching semiconductor, dielectric, or metal underlayers as shown in FIG. 5. The number of processing steps required to fabricate the feature is reduced with respect conventional processing techniques shown in FIGS. 1 and 2. As can be seen in FIG. 5, a substrate 30 is provided on which is deposited a material to be etched 32 (e.g., metal, dielectric or semiconductor layer). On layer 32 is deposited a hard mask 33 which is formed of the hybrid material of the present invention. The hard mask is selectively exposed to electromagnetic radiation or particle beam 34 followed by removal of non-exposed areas of the mask layer. Finally, the underlying layer 32 is etched via the pattern in the mask layer 33 (with an etch chemistry that is tailored to the material 32 and that will not remove to an appreciable degree mask 33). Etching can be accomplished through ion, vapor, or liquid methods.

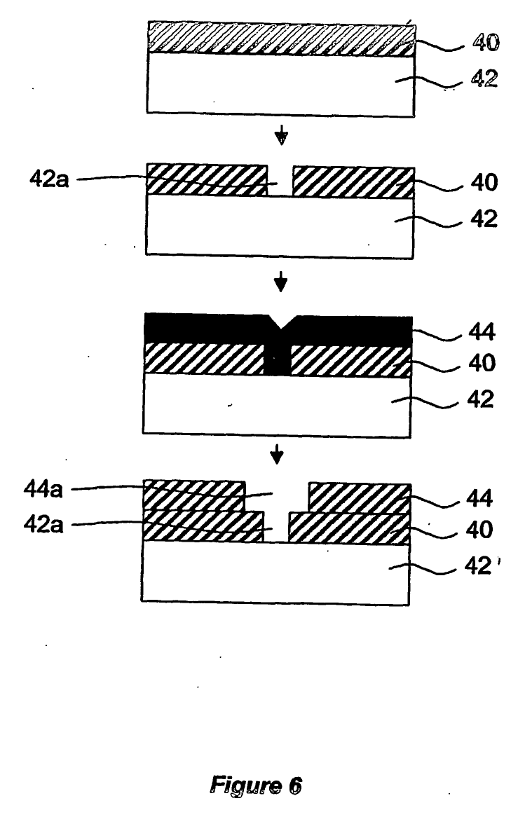

Owing to their “negative” behavior under exposure, the photopatternable dielectric materials of the present invention can also be applied to reduce the number of processing steps required to build a dielectric “dual damascene” structure. FIG. 6 illustrates one embodiment of this. First, the hybrid dielectric material is spun on or otherwise deposited as layer 42 on a substrate 40. Then, layer 42 is selectively exposed and developed to define a via 42a. Next, a “trench” layer 44 (also of the hybrid dielectric material of the invention) is deposited e.g., by spin on, exposed, and developed so as to form a trench 44a and reopen via 42a. No hard mask step or etch steps are required. Because of the negative developing characteristics of the material of the invention, the trench exposure needs no compensation to develop out the unexposed via area 44a filled by the material from trench layer 44.

In the above dual damascene example, either “via” layer 42 or “trench” layer 44, or both can be made of the hybrid, preferably photopatternable, material of the invention. Also, it is possible that though both layers 42 and 44 are hybrid materials of the invention, the hybrid material for layer 42 is different than the material for hybrid layer 44 (different inorganic backbone and/or organic groups discussed further below). Also, though a dual damascene example is illustrated in FIG. 6, a “single” damascene or other IC process could be performed—though preferably one that benefits from a photopatternable dielectric. Also, the dielectric materials of the present invention can be used in printed circuit board applications, similar to those discussed above for integrated circuit applications.

According to a first embodiment, the present invention comprises a chemical compound of the formula R1-R2-Si—(X1)3, wherein X1 is a halogen, acyloxy, alkoxy or OH group, R2 is an aromatic group having 6 carbon atoms and R1 is a substituent at position 4 of R2 selected from an alkyl group having from 1 to 4 carbon atoms, an alkenyl group having from 2 to 5 carbon atoms, an alkynyl group having from 2 to 5 carbon atoms, Cl or F.

According to a second embodiment, the present invention comprises a chemical compound of the formula R1-R2-Si—(X1)3, wherein X1 is a halogen, acyloxy, alkoxy or OH group, R2 is an organic polycyclic or bridged ring structure with Si bound to carbon position 1, and R1 is a substituent at position 3 or higher of R2 selected from an alkyl group having from 1 or more carbons atoms, an alkenyl, an alkynyl, an acrylate, an aryl, an alcohol, OH, H, D, Cl or F.

According to a third embodiment, the present invention comprises a chemical compound of the formula R1-R2-Si—(X1)3, wherein X1 is a halogen, acyloxy, alkoxy or OH group, R2 is an aromatic group having 8 carbon atoms and R1 is a substituent at position 5 of R2 selected from an alkyl group having from 1 to 4 carbon atoms, an alkenyl group having from 2 to 5 carbon atoms, an alkynyl group having from 2 to 5 carbon atoms, Cl or F.

According to a fourth embodiment, the present invention comprises a chemical compound of the formula R1-R2-Si—(X1)3, wherein X1 is a halogen, acyloxy, alkoxy or OH group, R2 is an aromatic group having 10 carbon atoms and R1 is a substituent at position 6 of R2 selected from an alkyl group having from 1 to 4 carbon atoms, an alkenyl group having from 2 to 5 carbon atoms, an alkynyl group having from 2 to 5 carbon atoms, Cl or F.

According to a fifth embodiment, a poly(organo siloxane) compound comprises a repeating Si—O backbone, carbon chain crosslinking groups and —R1-R2 bound to from 5% to 50% of the silicon atoms in the Si—O backbone, wherein R2 is an aromatic group having 6 carbon atoms and R1 is a substituent at position 4 of R2.

According to a sixth embodiment, a poly(organo siloxane) compound comprises a repeating Si—O backbone, —R1-R2 bound to from 25% to 50% of the silicon atoms in the Si—O backbone, wherein R2 is an aromatic group having 6 carbon atoms and R1 is a substituent at position 4 of R2 (again this could be drawn out for clarity), and R3 bound to from 5% to 50% of the silicon atoms, wherein R3 is an alkenyl group having from 2 to 5 carbon atoms, acrylic group or epoxy group.

According to a seventh embodiment, a poly(organo siloxane) compound comprises a repeating Si—O backbone, carbon chain crosslinking groups and —R1-2 bound to from 5% to 50% of the silicon atoms in the Si—O backbone, wherein R2 is polycyclic or bridged ring structure and R1 is a substituent at position 4 of R2 selected from an alkyl chain having from 1 to 4 carbons, H, D, F or OH.

According to an eight embodiment, a poly(organo siloxane) compound comprises a repeating Si—O backbone, —R1-R2 bound to from 25% to 50% of the silicon atoms in the Si—O backbone, wherein R2 is a polycyclic or bridged ring structure and R1 is a substituent at position 4 of R2 selected from H, D, P, OH, an alkyl group having from 1 to 4 carbon atoms, and an alkenyl group having from 2 to 5 carbon atoms, and further comprising R3 bound to from 5% to 50% of the silicon atoms, wherein R3 is an alkenyl group having from 2 to 5 carbon atoms, acrylic group, aryl group or epoxy group.

According to a ninth embodiment, a poly(organo siloxane) compound comprises a repeating Si—O backbone, carbon chain crosslinking groups and —R1-R2 bound to from 5% to 50% of the silicon atoms in the Si—O backbone, wherein R2 is an aromatic group having 8 carbon atoms and R1 is a substituent at position 5 of R2.

According to a tenth embodiment, a poly(organo siloxane) compound comprises a repeating Si—O backbone, —R1-R2 bound to from 25% to 50% of the silicon atoms in the Si—O backbone, wherein R2 is an aromatic group having 8 carbon atoms and R1 is a substituent at position 5 of R2 (again this could be drawn out for clarity), and R3 bound to from 5% to 50% of the silicon atoms, wherein R3 is an alkenyl group having from 2 to 5 carbon atoms, acrylic group or epoxy group.

According to an eleventh embodiment, a poly(organo siloxane) compound comprises a repeating Si—O backbone, carbon chain crosslinking groups and —R1-R2 bound to from 5% to 50% of the silicon atoms in the Si—O backbone, wherein R2 is an aromatic group having 10 carbon atoms and R1 is a substituent at position 6 of R2.

According to a twelfth embodiment, a poly(organo siloxane) compound comprises a repeating Si—O backbone, —R1-R2 bound to from 25% to 50% of the silicon atoms in the Si—O backbone, wherein R2 is an aromatic group having 10 carbon atoms and R1 is a substituent at position 6 of R2 (again this could be drawn out for clarity), and R3 bound to from 5% to 50% of the silicon atoms, wherein R3 is an alkenyl group having from 2 to 5 carbon atoms, acrylic group or epoxy group.

The present invention provides, for example, the following kinds of integrated circuits:
an integrated circuit having a layer with areas of an electrically conductive first material and an electrically insulating second material, wherein the second material is a poly(organo siloxane) compound comprising a repeating Si—O backbone, carbon chain crosslinking groups and —R1-R2 bound to from 5% to 50% of the silicon atoms in the Si—O backbone, wherein R2 is an aromatic group having 6 carbon atoms and R1 is a substituent at position 4 of R2;
an integrated circuit having a layer with areas of an electrically conductive first material and an electrically insulating second material, wherein the second material is a poly(organo siloxane) compound comprising a repeating Si—O backbone, carbon chain crosslinking groups and —R1-R2 bound to from 5% to 50% of the silicon atoms in the Si—O backbone, wherein R2 is a polycyclic or bridged ring structure and R1 is a substituent at position 4 of R2 selected from H, D, F, OH, an alkyl group having from 1 to 4 carbon atoms, and an alkenyl group having from 2 to 5 carbon atoms;
an integrated circuit having a layer with areas of an electrically conductive first material and an electrically insulating second material, wherein the second material is a poly(organo siloxane) compound comprising a repeating Si—O backbone, carbon chain crosslinking groups and —R1-R2 bound to from 5% to 50% of the silicon atoms in the Si—O backbone, wherein R2 is an aromatic group having 8 carbon atoms and R1 is a substituent at position 5 of R2; and
an integrated circuit having a layer with areas of an electrically conductive first material and an electrically insulating second material, wherein the second material is a poly(organo siloxane) compound comprising a repeating Si—O backbone, carbon chain crosslinking groups and —R1-R2 bound to from 5% to 50% of the silicon atoms in the Si—O backbone, wherein R2 is an aromatic group having 10 carbon atoms and R1 is a substituent at position 6 of R2.

A computer according to the invention comprises an integrated circuit of the above kind, having a layer with areas of an electrically conductive first material and an electrically insulating second material, wherein the second material is a poly(organo siloxane) compound comprising a repeating Si—O backbone, carbon chain crosslinking groups and —R1-R2 bound to from 5% to 50% of the silicon atoms in the Si—O backbone, wherein R2 is an aromatic group having 6 carbon atoms and R1 is a substituent at position 4 of R2). It can also have a layer with areas of an electrically conductive first material and an electrically insulating second material, wherein the second material is a poly(organo siloxane) compound comprising a repeating Si—O backbone, carbon chain crosslinking groups and —R1-R2 bound to from 5% to 50% of the silicon atoms in the Si—O backbone, wherein R2 is a polycyclic or bridged ring structure and R1 is a substituent at position 4 of R2. Further, the integrated circuit of the computer can have a layer with areas of an electrically conductive first material and an electrically insulating second material, wherein the second material is a poly(organo siloxane) compound comprising a repeating Si—O backbone, carbon chain crosslinking groups and —R1-R2 bound to from 5% to 50% of the silicon atoms in the Si—O backbone, wherein R2 is a polycyclic or bridged ring structure and R1 is a substituent at position 4 of R2.

A computer according to the invention can further comprise an integrated circuit having a layer with areas of an electrically conductive first material and an electrically insulating second material, wherein the second material is a poly(organo siloxane) compound comprising a repeating Si—O backbone, carbon chain crosslinking groups and —R1-R2 bound to from 5% to 50% of the silicon atoms in the Si—O backbone, wherein R2 is an aromatic group having 8 carbon atoms and R1 is a substituent at position 5 of R2) or having a layer with areas of an electrically conductive first material and an electrically insulating second material, wherein the second material is a poly(organo siloxane) compound comprising a repeating Si—O backbone, carbon chain crosslinking groups and —R1-R2 bound to from 5% to 50% of the silicon atoms in the Si—O backbone, wherein R2 is an aromatic group having 10 carbon atoms and R1 is a substituent at position 6 of R2.

In the method for making an integrated circuit, alternating areas of electrically insulating and electrically conducting materials within a layer on a semiconductor substrate, wherein the electrically insulating material comprises any of the above poly(organo siloxane) compounds.

The chemical compounds of the formula R1-R2-Si—(X2)3, wherein X2 is a halogen or an alkoxy group, R2 is an aromatic group having 6 carbon atoms and R1 is a substituent at position 4 of R2, R1 being selected from an alkyl group having from 1 to 4 carbon atoms, an alkenyl group having from 2 to 5 carbon atoms, or OH, can be produced by a (Grignard-type) process comprising the steps of:
reacting R1-R2-Br with Mg and Si—(OR3)4 to form R1-R2-Si—(OR3)3+BrMgOR, where R1 is selected from an alkyl group having from 1 to 4 carbon atoms, an alkenyl having from 2 to 5 carbon atoms, R2 is an aromatic or non-aromatic ring structure having from 5 to 7 carbon atoms, and R3 is an alkoxy group having from 1 to 3 carbon atoms; and
reacting R1-R2-Si—(OR3)3 with 3 SO2Cl2 in the presence of C5H5N—HCl to yield R1-R2-SiCl3+3 SO2+3EtCl.

Such a process can be used for preparing a chemical compound of the formula R1-R2-Si—(X2)3, wherein X2 is a halogen or alkoxy group, R2 is an aromatic group and R1 is a substituent at position 4 of R2, R1 being selected from an alkyl group having from 1 to 4 carbon atoms, an alkenyl, an alkynyl, F, whereby R1-R2-Br is reacted with Mg and Si—(OR3)4 to form R1-R2-Si—(OR3)3+BrMgOR, where R1 is selected from an alkyl group having from 1 to 4 carbon atoms, R2 is an aromatic or non-aromatic ring structure having from 5 to 7 carbon atoms, and R3 is an alkoxy group having from 1 to 3 carbon atoms; and R1-R2-Si—(OR3)3 is reacted with 3 SO2Cl2 in the presence of C5H5N—HCl to yield R1-R2-SiCl3+3 SO2+3EtCl.

Similarly, a chemical compound of the formula R1-R2-Si—(X2)3, wherein X2 is a halogen or alkoxy group, R2 is an aromatic group having 8 carbon atoms and R1 is a substituent at position 5 of R2, R1 being selected from an alkyl group having from 1 to 4 carbon atoms, an alkenyl group having from 2 to 5 carbon atoms, or OH, can be prepared by reacting R1-R2-Br with Mg and Si—(OR3)4 to form R1-R2-Si—(OR3)3+BrMgOR, where R1 is selected from an alkyl group having from 1 to 4 carbon atoms, an alkenyl having from 2 to 5 carbon atoms, R2 is an aromatic or non-aromatic ring structure having from 5 to 7 carbon atoms, and R3 is an alkoxy group having from 1 to 3 carbon atoms; and reacting R1-R2-Si—(OR3)3 with 3 SO2Cl2 in the presence of C5H5N—HCl to yield R1-R2-SiCl3+3 SO2+3EtCl.

A chemical compound of the formula R1-R2-Si—(X2)3, wherein X2 is a halogen or alkoxy group, R2 is an aromatic group having 10 carbon atoms and R1 is a substituent at position 6 of R2, R1 being selected from an alkyl group having from 1 to 4 carbon atoms, an alkenyl group having from 2 to 5 carbon atoms, or OH, can be prepared by reacting R1-R2-Br with Mg and Si—(OR3)4 to form R1-R2-Si—(OR3)3+BrMgOR, where R1 is selected from an alkyl group having from 1 to 4 carbon atoms, an alkenyl having from 2 to 5 carbon atoms, R2 is an aromatic or non-aromatic ring structure having from 5 to 7 carbon atoms, and R3 is an alkoxy group having from 1 to 3 carbon atoms; and reacting R1-R2-Si—(OR3)3 with 3 SO2Cl2 in the presence of C5H5N—HCl to yield R1-R2-SiCl3+3 SO2+3EtCl.

According to the invention, a thin film comprising a composition can be obtained by hydrolyzing a monomeric silicon compound having at least one hydrocarbyl radical, containing an unsaturated carbon-to-carbon bond, and at least one hydrolyzable group attached to the silicon atom of the compound with another monomeric silicon compound having at least one aryl group and at least one hydrolyzable group attached to the silicon atom of the compound to form a siloxane material.

In the above formulas, R₁ is typically a linear or branched carbon chain having from 1 to 4 carbons, which is optionally fluorinated or perfluorinated. Thus, R₁ can be selected from the group consisting of —CF₃, —CF₂CF₃, —CF₂CF₂CF₃, —CF₂OH, —CF₂CF₂OH, —CF₂(CF₂)₂OH, —CF₂(CF₂)₂CF₃, —CF₂(CF₂)₃OH, a carbon chain having a carbon-carbon double bond and from 2 to 5 carbons, a vinyl group, an acrylic group, an alkenyl group having from 1 to 4 carbons, and —Si—(X₂)₃, where X₂ is a halogen (X₁ is preferably chlorine or ethoxy, X₂ is chlorine). R₁ can also be —CH₃, —CH₂CH₃, —CH₂CH₂CH₃, —(CH₂)CF₃, —CH₂CH₂OH or —CH₂CF₂OH.

R₂ is an aromatic group selected from the group of aromatic groups having 5 or 6 carbon atoms and further substituted at positions 3 and 5. It can be substituted at positions 3 and 5 with a group —CF₃.

In poly(organo siloxane) compounds comprising a repeating Si—O backbone, wherein there is a group R3 bound to, for example, from 5% to 50% of the silicon atoms, such a group R3 is an alkenyl group having from 2 to 5 carbon atoms, acrylic group or epoxy group. Typically, R₃ is an epoxy group, such as a glycidoxypropyl group, an acrylic group, an acryl group, such as a methacrylic group, an alkenyl group having from 2 to 5 carbon atoms, a vinyl group.

The compounds can also comprise R₄ groups bound to from 5 to 50% of the silicon atoms of the Si—O backbone, wherein R₄ is an alkyl group having from 1 to 4 carbon atoms. Examples of R₄ include CH₃, CH₂CH₃, (CH₂)₂CH₃, CF₃, CF₂CF₃ and (CF₂)₂CF₃.

In one embodiment, the composition comprises a poly(organosiloxane) obtained by hydrolyzing a first silicon compound having the general formula I
Y1₃₋ₐ-SiR1_{b}R2_{c}R3_{d} I
wherein
Y1 represents a hydrolyzable group;
R1 is an aromatic group having 6 carbon atoms and R1 is a substituent at position 4 of R1 selected from an alkyl group having from 1 to 4 carbon atoms, an alkenyl group having from 2 to 5 carbon atoms, an alkynyl group having from 2 to 5 carbon atoms, Cl or F;
R2 and R3 are independently selected from hydrogen, substituted or non-substituted alkyl groups, substituted or non-substituted alkenyl and alkynyl groups, and substituted or non-substituted aryl groups;
a is an integer 0, 1 or 2;
b is an integer a+1;
c is an integer 0, 1 or 2;
d is an integer 0 or 1; and
b+c+d=3
with a second silicon compound having the general formula II
   Y2₃₋ₑ-SiR4_{f}R5_{g}R6ₕ II
   wherein
Y2 represents a hydrolyzable group;
R4 is an aromatic group having 6 carbon atoms and R4 is a substituent at position 4 of R4 selected from an alkyl group having from 1 to 4 carbon atoms, an alkenyl group having from 2 to 5 carbon atoms, an alkynyl group having from 2 to 5 carbon atoms, Cl or F;
R5 and R6 are independently selected from hydrogen, substituted or non-substituted alkyl groups, substituted or non-substituted alkenyl and alkynyl groups, and substituted or non-substituted aryl groups;
e is an integer 0, 1 or 2;
f is an integer e+1;
g is an integer 0, 1 or 2;
h is an integer 0 or 1; and
f+g+h=3.

The present invention provides novel siloxane materials, which can be hydrolyzed and condensed (alone or with one or more other compounds) into a hybrid material having a (weight average) molecular weight of from 500 to 100,000 g/mol. The molecular weight can be in the lower end of this range (e.g., from 500 to 5,000 g/mol, or more preferably 500 to 3,000 g/mol) or the hybrid material can have a molecular weight in the upper end of this range (such as from 5,000 to 100,000 g/mol or from 10,000 to 50,000 g/mol). In addition, it may be desirable to mix a hybrid material having a lower molecular weight with a hybrid material having a higher molecular weight. The hybrid material can be suitably deposited such as by spin-on, spray coating, dip coating, or the like, as will be explained in more detail below.

The dielectric constant of the present materials can be lowered by rapid thermal curing (RTC), as described in our copending International Patent Application titled “Organo-silsesquioxane polymers for forming low-k dielectrics”. However, it should be pointed out that the present materials can also be processed by conventional thermal processing.

The dielectric constant of the densified material is 2.70 or less, advantageously 2.60 or less, preferably 2.50 or less, in particular 2.40 or less, and suitably 2.30 or less. The CTE of the film is less than 25 * 10⁻⁶ l/deg C.

The material can be characterized as being “nonporous” which, in the present context means, in particular, that the porosity is low, typically less than 25%, preferably less than 20%, in particular less than 15% (by volume), and the average pore size is less than 5 nm, preferably less than 2 nm and in particular less than 1 nm. As a result of the processing, the electronic polarizability of the film is decreased more than 0.1 compared to a predetermined value obtained by conventional processing, as explained above.

As mentioned above, the nonporous dielectric material can be subjected to annealing or a similar pretreatment or post-treatment of heated to the second temperature, i.e. the actual curing temperature. Annealing is carried out, e.g., by a process in which the material is subjected to UV radiation, DUV radiation, Extreme UV radiation, IR radiation or e-beam radiation or a combination thereof. The annealed material is then subjected to curing at an elevated temperature in air, nitrogen, argon, forming gas or vacuum.

The pre-cure and rapid cure processes according to the present invention, result in a dielectric film free of silanols (less 0.5 wt-%).

The annealed and cured (densified, crosslinked) material can be subjected to deposition of a second layer selected from a metal, a barrier, a liner or an additional dielectric layer.

Based on the above, the present invention provides a process for preparing a siloxane-based dielectric material on a semiconductor substrate by hydrolysis and condensation of corresponding reactants, applying the prepared compositions on a substrate in the form of a thin layer, patterning the film by selective radiation and developing the radiated film and curing the formed structure.

As an embodiment of the above process, the material above is processed first by introducing a monomeric or polymerized material on a semiconductor substrate by a spin-on or CVD method, and then forming a siloxane polymer film on the semiconductor substrate by activating polymerization and densification reactions by rapid curing processing so as to produce a material having a relative dielectric constant lower than 2.6, preferably less than 2.5, in particular less than 2.4. Typically the dielectric constant is between 2.0 and <2.6.

The pore size of the nonporous dielectric material is less than 2 nm, the co-efficient of thermal expansion less than 25 ppm/deg C., and the thermal decomposition temperature higher than 450° C.

The electrically insulating material can be baked and patterned, with an electrically conductive material being deposited in removed areas of the patterned dielectric. The electrically conductive material comprises, for example, copper.

The above process is, e.g., a dual damascene process.

The deposition and patterning processes are described, for instance, in our earlier application PCT/FI03/00036, the disclosure of which is herewith incorporated by reference.

Design of Molecules

All actual calculations were done using Gaussian-98 computational chemistry program. The structures of each molecule were built using ChemDraw and Chem3D Pro programs. The Chem3D includes MOPAC package and the initial structural optimizations were done using AM1 theory.

In Gaussian LSDA theory was used to describe the exchange- and correlation. LSDA is a reliable method for electronic densities and quantities like that. It does not describe well the weak molecule-molecule bonds. In this molecule design work, the properties of interest are related to electron density.

The used basis set was cc-pVDZ. Also larger basis sets, viz. 6-311+(2d) and aug-cc-pVDZ, were tested. The dipole moments did not change much but the polarizations were found to be rather sensitive to the basis.

The structural optimizations were done starting form the Chem3D/AM1 optimized structures. In case of mol10, different conformations of the molecules were tested. The reported numbers were from the lowest energy structure. The optimization for the larger molecules was done using the loose option in Gaussian. This was necessary because the molecules are rather flexible, they will change their structures somewhat but the energy will not change much. This should not effect to the main conclusions or trends of the calculations. All structures were optimized with LSDA and cc-pVDZ basis.

The effective charges were computed using the Merz-Collman fitting procedure to reproduce the true electrostatic potential. (prop=fitcharge and pop=mk, keywords in Gaussian). The local dipole moments are based on these effective charges.

Last the bond stretching calculations were done using the optimized geometries and stretching a single bond with constant steps of 0.05 Å.

Based on the calculations, some molecules were synthesized as precursors to obtain low-k dielectric films with optimal electrical thermal and mechanical properties.

The synthesis methods involved the following steps. Generally, the Grignard reaction can be carried out at room temperature or at an elevated temperature (temperature 10 to 70 deg C., in particular about 20 to 50 deg C.). Depending on the quality of the elemental magnesium used, it is possible or recommendable to add some iodine or to ultrasonicate the reaction mixture. In addition to the mild halogenating agent formed by the combination of thionyl chloride and pyridyl hydrochloride it is possible to use other agents capable of replacing the alkoxy groups with halogens without hydrolyzing of oxidizing the group R2. As an example of such substances, carbon tetrachloride can be mentioned.

Synthesis of Molecules

### (#1) 4-(trifluoromethyl)phenyl trichlorosilane, 4-(F₃C)C₆H₄SiCl₃

Preparation:

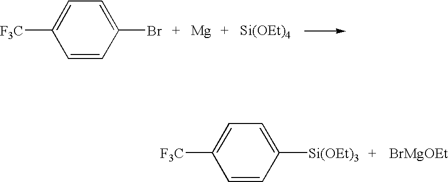

First, 96.24 g (0.427 mol) 4-(trifluoromethyl)phenyl bromide, 10.38 g (0.427 mol) magnesium, and a small amount of iodine were stirred for half an hour. Then, 356.78 g (382 ml, 1.708 mol) Si(OEt)₄ was added to the solution. Et₂O was added until exothermic reaction occurred (˜200 ml) and the solution was refluxed overnight. Et₂O was evaporated off and 250 ml n-heptane added. Mg-salts were filtered off, and n-heptane evaporated. The remaining 4-(F₃C)C₆H₄Si(OEt)₃ was purified by distillation. Bp 68° C./1 mbar. Yield 50.22 g (38%).

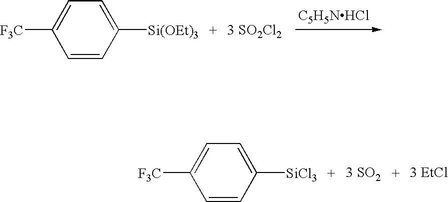

The product of the preceding steps, viz. 50.22 g (0.163 mol) 4-(trifluoromethyl)phenyl triethoxysilane, was mixed with 83 mL (1.140 mol, 135.62 g) thionylchloride and 2.45 g (0.021 mol) pyridinium hydrochloride, and the mixture was refluxed and stirred for 16 h. Excess of SO₂Cl₂ was evaporated and the residue was fractionally distilled to obtain 37 g (81%) 4-(trifluoromethyl)phenyl trichlorosilane. Bp 44° C./4.0 mbar.

Characterization:

4-(trifluoromethyl)phenyl triethoxysilane, 4-(CF₃)C₆H₄Si(OEt)₃

NMR (Et₂O):
²⁹Si: −63.0 ppm
¹³C, 139.3 ppm (C₁)
   137.4 ppm (C_{2,6})
   126.4 ppm (C_{3,5})
   134.4 ppm (qu, C₄), ²J_{C4-F} 31.7 Hz
   126.6 ppm (qu, C₇), ¹J_{C7-F} 271.4 Hz
   60.8 ppm (C₈)
   20.0 ppm (C₉)
4-(trifluoromethyl)phenyl trichlorosilane, 4-(CF₃)C₆H₄SiCl₃

NMR (Et₂O):
²⁹Si: −1.5 ppm
¹³C, 138.1 ppm (C₁)
   136.0 ppm (C_{2,6})
   127.7 ppm (C_{3,5})
   137.0 ppm (qu, C₄), ²J_{C4-F} 33.3 Hz
   125.9 ppm (qu, C₇), ¹J_{C7-F} 272.2 Hz
¹⁹F: −65.3 ppm

### (#2) 3,5-Bis(trifluoromethyl)phenyl trichlorosilane, 3,5-(F₃C)₂C₆H₃SiCl₃

Preparation:

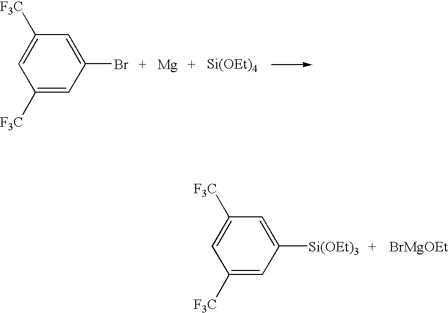

First, 125.11 g (0.427 mol) 3,5-bis(trifluoromethyl)phenyl bromide, 10.38 g (0.427 mol) magnesium, and a small amount of iodine were stirred for half an hour. Then, 356.78 g (382 ml, 1.708 mol) Si(OEt)₄ were added to the solution. Et₂O was added until exothermic reaction occurred (˜200 ml) and the solution was refluxed overnight. Et₂O was evaporated off and 250 ml n-heptane added. The Mg-salts were filtered off and n-heptane evaporated.

The remaining 3,5-(F₃C)₂C₆H₃Si(OEt)₃ was purified by distillation. Bp 80° C./0.8 mbar. Yield 78.72 g (52%).

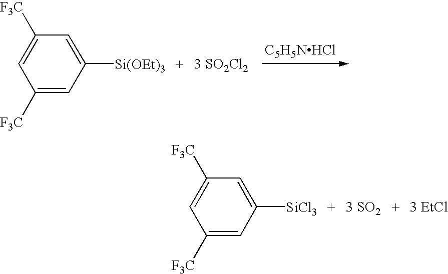

The product of the preceding step, viz. 61.35 g (0.163 mol) 3,5-bis(trifluoromethyl)phenyl triethoxysilane, was mixed with 83 mL (1.140 mol, 135.62 g) thionylchloride and 2.45 g (0.021 mol) pyridinium hydrochloride, and the mixture was refluxed and stirred for 16 h. Excess of SO₂Cl₂ was evaporated and the residue was fractionally distilled to obtain 44.2 g (78%) of 3,5-bis(trifluoromethyl)phenyl trichlorosilane. Bp 41° C./3.1 mbar.

### (#3) Pentafluorophenyl methyl trichlorosilane, C₆F₅CH₂SiCl₃

Preparation:

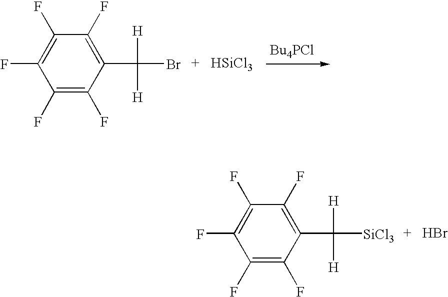

First, 106.29 g (0.407 mol) pentafluorophenylmethyl bromide, 1.20 g (0.004 mol) Bu₄PCl, and 187.55 g (140 ml, 1.385 mol) HSiCl₃ were added to high pressure vessel. The solution was heated to 150° C. for four hours. Excess HSiCl₃ was evaporated and C₆F₅CH₂SiCl₃ was purified by distillation. Bp 56° C./2.4 mbar. Yield 91.18 g (71%).

Other applicable precursors based on molecular modeling are, but not limited to, the following:

| | | |
|---|---|---|
| (#4) | 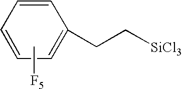 | Pentafluorophenyl ethyl trichlorosilane |
| (#5) | 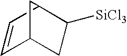 | Norbornyl trichlorosilane |
| (#6) | 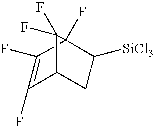 | Pentafluoronorbornyl trichlorosilane |
| (#7) | 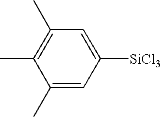 | 3,4,5-trimethylphenyl trichlorosilane |
| (#8) | 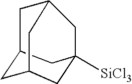 | Adamantyl trichlorosilane |
| (#9) | 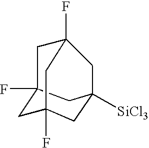 | 3,5,7-trifluoroadamantyl trichlorosilane |
| (#10) | 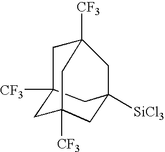 | 3,5,7-trifluoromethyl- adamantyl trichlorosilane |
| (#11) | 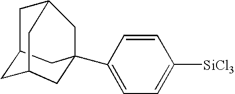 | Adamantylphenyl trichlorosilane |
| (#12) | 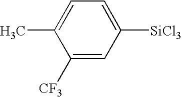 | 3-trifluoromethyl-4- (methyl)phenyl trichlorosilane |
| (#13) | 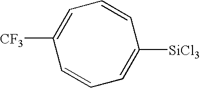 | 5-trifluoromethyl cyclooctatetraenetri- chlorosilane |
| (#14) | 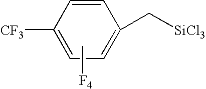 | 4-trifluoromethyl tetrafluorophenyl methyl trichlorosilane |

Synthesis of Polymers

### EXAMPLE A

### 4-(trifluoromethyl)phenyl trichlorosilane 80 mole-%

Vinyl trichlorosilane (0.05 mol), 4-trifluoromethyl phenyl trichlorosilane (0.80 mol) and methyl trichlorosilane (0.15 mol) are dissolved in dehydrated DCM (800 ml). The solution is added drop-wise into a flask containing excess of water (45 mol) while stirring the solution. After addition of water, the solution stirred for 1 hour at the room temperature. The solution is neutralized by water extraction for 12 times and finally volatile components are evaporated with rotary evaporator. After vacuum treatment, dehydrated 300 w-% of mesitylene used as process solvent is added into the material and the material is carefully homogenized. Appropriate initiators are added and dissolved into the mixture. Finally the material is filtered.

### EXAMPLE B

### Pentafluorophenyl methyl trichlorosilane 80 mole-%

Vinyl trichlorosilane (0.05 mol), pentafluorophenyl methyl trichlorosilane (0.80 mol) and methyl trichlorosilane (0.15 mol) are dissolved in dehydrated DCM (800 ml). The solution is added drop-wise into a flask containing excess of water (45 mol) while stirring the solution. After addition of the water, the solution stirred for 1 hour at the room temperature. The solution is neutralized by water extraction for 12 times and finally volatile components are evaporated with rotary evaporator. After vacuum treatment, dehydrated 300 w-% of mesitylene used as process solvent is added into the material and the material is carefully homogenized. Appropriate initiators are added and dissolved into the mixture. Finally the material is filtered.

Alternative procedures for each stage:

Instead of DCM (dichloromethane) as a solvent any pure solvent or a mixture of solvents/alternate solvents can be used either by themselves or in combinations. Traditional methods of selecting solvents by using Hansen type parameters can be used to optimize these systems. Examples of suitable solvents are acetone, dichloromethane, chloroform, diethyl ether, ethyl acetate, methyl-isobutyl ketone, methyl ethyl ketone, acetonitrile, ethylene glycol dimethyl ether, triethylamine, formic acid, nitromethane, 1,4-dioxane, pyridine, acetic acid, di-isopropyl ether, toluene, carbon disulphide, carbon tetrachloride, benzene, methylcyclohexane, chlorobenzene. Water used in the reaction can be dissolved into pure or mixtures of following solvents: acetone, dichloromethane, chloroform, diethyl ether, ethyl acetate, methyl-isobutyl ketone, methyl ethyl ketone, acetonitrile, ethylene glycol dimethyl ether, triethylamine, formic acid, nitromethane, 1,4-dioxane, pyridine, acetic acid, di-isopropyl ether, toluene, carbon disulphide, carbon tetrachloride, benzene, methylcyclohexane, chlorobenzene. In place of water, the following reagents can be used: deuterium oxide (D₂O) or HDO. A part of the water can be replaced with the following reagents: alcohols, deuterium alcohols, fluorinated alcohols, chlorinated alcohols, fluorinated deuterated alcohols, chlorinated deuterated alcohols. The reaction mixture may be adjusted to any appropriate temperature. Water can be added into the precursor solution. Even less than an equivalent amount of water can be used.

Instead of water extraction, neutralization (removal of the hydrochloric acid) can be performed using the following chemicals: sodium hydrogen carbonate (NaHCO₃), pure potassium hydrogen carbonate (KHCO₃), ammonium hydrogen carbonate (NH₄HCO₃), sodium carbonate (Na₂CO₃), potassium carbonate (K₂CO₃), sodium hydroxide (NaOH), potassium hydroxide (KOH), calcium hydroxide (Ca(OH)₂), magnesium hydroxide (Mg(OH)₂) ammonia (NH₃), trialkylamines (R₃N, where R is hydrogen or a linear or branched chain CₓH_{y}, x<10, as for example in triethylamine, or heteroatom containing as for example in triethanol amine), trialkyl ammonium hydroxides (R₃NOH, R₃N, wherein R is hydrogen or straight/branched chain CₓH_{y}, x<10), alkali metal silanolates, alkali metal silaxonates, alkali metal carboxylates. All neutralization reagents can be added into the reaction mixture also as a solution of any appropriate solvent. Acidic or basic water solution can be used in the extraction. Neutralization can be performed also with standard evaporation under vacuum or with azeotropic water evaporation. Procedure for azeotropic water evaporation: The solvent is evaporated off after the hydrolysis. The material is dissolved into mixture of water and one of the following solvents (1:10 volume/volume): tetrahydrofuran, ethanol, acetonitrile, 2-propanol, tert-butanol, ethylene glycol dimethyl ether, 2-propanol. The formed solution is evaporated to dryness. The material is dissolved again into the same mixture of water and the solvent. Evaporation and addition cycle is repeated until pH value of the material solution is 7. The solvent is then evaporated with rotary evaporator. The pressure in this stage can be in a large range. The material can be heated while vacuum treatment.

The molecular weight of formed polymer can be increased by using base or acid catalyzed polymerizations. By increasing the molecular weight, the mechanical properties of the film can be improved. On the other hand, a too large molecular weight may impair the film-forming process, e.g. the spinning. Thus, by controlling the molecular weight of the hydrolysed composition, processing of the composition and the properties of the film can be adjusted.

In the following, the procedures for increasing the molecular weight are described in more detail:

Procedure for acid catalyzed polymerization: The pure material is dissolved into any appropriate solvent, such as tetrahydrofuran, ethanol, acetonitrile, 2-propanol, tert-butanol, ethylene glycol dimethyl ether, 2-propanol, toluene, dichloromethane, xylene, chloroform, diethyl ether, ethyl acetate, or methyl-isobutyl ketone. Into the solution, a catalytic amount of an acid, such as triflic acid, monofluoro acetic acid, trifluoro acetic acid, trichloro acetic acid, dichloro acetic acid, monobromo acetic acid, is added. The solution is refluxed for few hours or until polymerization has reached the desired level while water formed in the reaction is removed. After polymerization, the acid catalyst is removed from the material solution completely, for example by using solvent extraction or other methods described in alternative neutralization section. Finally, the solvent is removed.

Procedure for base catalyzed polymerization: The pure material is dissolved into any appropriate solvent, such as tetrahydrofuran, ethanol, acetonitrile, 2-propanol, tert-butanol, ethylene glycol dimethyl ether, 2-propanol, toluene, dichloromethane, xylene, chloroform, diethyl ether, ethyl acetate, or methyl-isobutyl ketone. Into the solution, a catalytic amount of a base, such as triethanol amine, triethyl amine, pyridine, ammonia, or tributyl ammonium hydroxide, is added. The solution is refluxed for few hours or until polymerization has reached the desired level while water formed during the reaction is removed. After polymerization, the base catalyst is removed from the material solution completely, for example by adding acidic water solution into the material solution. After that, the acidic solution is neutralized using solvent extraction or other methods described in alternative neutralization section. Finally, the solvent is removed.

In place of mesitylene it is possible to use any or a mixture of the following solvents: methyl-isobutyl ketone, 2-propanol, ethanol, butyl acetate, methanol, 1-propanol, tetrahydrofuran, acetone, nitromethane, chlorobenzene, dibutyl ether, cyclohexanone, 1,1,2,2-tetrachloroethane, trichloroethanes, ethyl lactate, 1,2-propanediol monomethyl ether acetate, carbon tetrachloride, perfluoro toluene, perfluoro p-xylene, perfluoro iso-propanol, tetraethylene glycol, 2-octanol, dimethyl sulfoxide, 2-ethyl hexanol, 3-octanol, diethyleneglycol butyl ether, diethyleneglycol dibutyl ether, diethylene glycol dimethyl ether, n-propoxy propanol, 1,2,3,4-tetrahydronaphtalene or trimethylol propane triacrylate.

The material solution can be acidified using, e.g., the following acids: acetic acid, formic acid, propanoic acid, monofluoro acetic acid, trifluoro acetic acid, trichloro acetic acid, dichloro acetic acid, monobromo acetic acid. Also the following basic compounds can be added to the material solution: triethyl amine, triethanol amine, pyridine, N-methyl pyrrolidone. Mesitylene or any other synthesis or process solvent can be introduced in any stage by keeping material all the time in liquid form. Therefore formation of solvent free material during synthesis between certain stages is not necessary. This sometimes beneficial operation can be done by using so called solvent replacement method. In this method a solvent having lower boiling point can be replaced in the solution with another solvent having higher boiling point. By adding higher boiling point solvent into the solution followed by evaporation-addition cycles, the solvent with lower boiling point will be replaced gradually with the other solvent or solvent mixture of any desired dilution.

Photoinitiators that can be used are Irgacure 184, Irgacure 500, Irgacure 784, Irgacure 819, Irgacure 1300, Irgacure 1800, Darocure 1173 and Darocure 4265. The initiator can be highly fluorinated, such as 1,4-bis(pentafluorobenzoyl)benzene or Rhodosil 2074. Thermal initiators which can be used include benzoyl peroxide, 2,2′-azobisisobutyronitrile, 1,1′-azobis(cyclohexanecarbo-nitrile), tert.-butyl hydroperoxide, dicumyl peroxide and lauroyl peroxide, but are not limited to these. Thermal initiators are optimized for their reactivity, thermal stability as well as chain transfer efficiencies. Typical radical initiators listed below work well with the system as well as other charge transfer catalysts that can be used as initiators.

Anhydrous inorganic compounds, including but not limited to sulfate compounds, such as sodium sulfate (Na₂SO₄) and magnesium sulfate (MgSO₄), may be used to remove water and moisture out of organic as well as organic-inorganic solutions. These compounds are insoluble in most organic solvents and they easily bind water to so called crystal water.

The present invention describes the use of anhydrous inorganic compounds as novel and effective drying (removal of water) agents of metalalkoxide and organo-metal chloride based optical materials in ethyl acetate, toluene or tetrahydrofurane solutions. Removal of water and moisture is crucial to minimize optical losses due the entrapped water molecules into the final optical material. The drying is proceeded by adding appropriate amounts of drying agent into the solution. The amount depends on the character of the drying agent and on the amount of water to be removed. It is safe to use an excess of the drying agent. The dried solution is then filtered and the solvent evaporated off. Traces of solvents are removed with high vacuum treatment.

Tetrahydrofurane, ethyl acetate and toluene form an azeotrope with water when boiled. So if the drying with these agents is not complete the remaining water is removed when the solvent is evaporated.

The use of drying agents may slightly increase the concentration of inorganic impurities of the optical material at least if the drying is not completed before evaporation of the solvent.

The materials disclosed herein can be used in methods and devices such as set forth in Exhibit A attached herein.

1. A chemical compound of the general formula
R₁—R₂—Si—(X₁)₃,
wherein
X₁ is a leaving group,
R₂ is a cycloalkyl having from 3 to 16 carbon atoms, an aryl having from 5 to 18 carbon atoms or a polycyclic alkyl group having from 7 to 16 carbon atoms, and
R₁ is a substituent of R₂ selected from alkyl groups having from 1 to 4 carbon atoms, alkenyl groups having from 2 to 5 carbon atoms, alkynyl groups having from 2 to 5 carbon atoms, and aromatic groups having 5 or 6 carbon atoms, each of said groups being optionally substituted, and Cl and F.

2-9. (canceled)

10. A poly(organo siloxane) compound comprising a repeating Si—O backbone, carbon chain cross-linking groups and —R₁—R₂ bound to from 5% to 50% of the silicon atoms in the Si—O backbone, wherein R₂ is an aromatic group having 6 carbon atoms and R₁ is a substituent at position 4 of R₂.

11-28. (canceled)

29. A poly(organo siloxane) compound comprising a repeating Si—O backbone, —R1-R2 bound to from 25% to 50% of the silicon atoms in the Si—O backbone, wherein R2 is an aromatic group having 6 carbon atoms and R1 is a substituent at position 4 of R2, and R3 bound to from 5% to 50% of the silicon atoms, wherein R3 is an alkenyl group having from 2 to 5 carbon atoms, acrylic group or epoxy group.

30-40. (canceled)

41. An integrated circuit having a layer with areas of an electrically conductive first material and an electrically insulating second material, wherein the second material is a poly(organo siloxane) compound comprising a repeating Si—O backbone, carbon chain crosslinking groups and —R1-R2 bound to from 5% to 50% of the silicon atoms in the Si—O backbone, wherein R2 is an aromatic group having 6 carbon atoms and R1 is a substituent at position 4 of R2.

42-56. (canceled)

57. A method of making a chemical compound of the formula R₁—R₂—Si—(X₂)₃, wherein X₂ is a halogen, R₂ is an aromatic group having 5 to 18 carbon atoms, a cycloalkyl having from 3 to 16 carbon atoms, or a polycyclic alkyl group having from 7 to 16 carbon atoms, and R₁ is a substituent, in particular at position 4 of R₂, R₁ being selected from the group consisting of alkyl groups having from 1 to 4 carbon atoms, alkenyl groups having from 2 to 5 carbon atoms, and OH groups, comprising:
reacting a compound of the formula R₁—R₂—Br, wherein R₁ and R₂ have the same meaning as above, with Mg and with a compound of the formula Si—(OR₃)₄, wherein R₃ is an alkoxy group having from 1 to 3 carbon atoms, to form a compound of the formula R₁—R₂—Si—(OR₃)₃, wherein R₁, R₂ and R₃ have the same meaning as above;
reacting the thus obtained compound of the formula R₁—R₂—Si—(OR₃)₃ with a halogenating agent capable of replacing, preferably each, R₃ with a halogen substantially without affecting the rest of the compound of formula R₁—R₂—Si—(OR₃)₃ to produce a compound of the formula R₁—R₂—SiX₂, wherein R₁, R₂ and X₂ have the same meaning as above, and
recovering the thus obtained compound.

58. (canceled)

59. A chemical compound of the formula R1-R2-Si—(X1)3, wherein X1 is a halogen, acyloxy, alkoxy or OH group, R2 is an organic polycyclic or bridged ring structure with Si bound to carbon position 1, and R1 is a substituent at position 3 or higher of R2 selected from an alkyl group having from 1 or more carbons atoms, an alkenyl, an alkynyl, an acrylate, an aryl, an alcohol, OH, H, D, Cl or F.

60-67. (canceled)

68. A poly(organo siloxane) compound comprising a repeating Si—O backbone, carbon chain crosslinking groups and —R1-R2 bound to from 5% to 50% of the silicon atoms in the Si—O backbone, wherein R2 is polycyclic or bridged ring structure and R1 is a substituent at position 4 of R2 selected from an alkyl chain having from 1 to 4 carbons, H, D, F or OH.

69-84. (canceled)

85. A poly(organo siloxane) compound comprising a repeating Si—O backbone, —R1-R2 bound to from 25% to 50% of the silicon atoms in the Si—O backbone, wherein R2 is a polycyclic or bridged ring structure and R1 is a substituent at position 4 of R2 selected from H, D, F, OH, an alkyl group having from 1 to 4 carbon atoms, and an alkenyl group having from 2 to 5 carbon atoms, and further comprising R3 bound to from 5% to 50% of the silicon atoms, wherein R3 is an alkenyl group having from 2 to 5 carbon atoms, acrylic group, aryl group or epoxy group.

86-98. (canceled)

99. An integrated circuit having a layer with areas of an electrically conductive first material and an electrically insulating second material, wherein the second material is a poly(organo siloxane) compound comprising a repeating Si—O backbone, carbon chain crosslinking groups and —R1-R2 bound to from 5% to 50% of the silicon atoms in the Si—O backbone, wherein R2 is a polycyclic or bridged ring structure and R1 is a substituent at position 4 of R2 selected from H, D, F, OH, an alkyl group having from 1 to 4 carbon atoms, and an alkenyl group having from 2 to 5 carbon atoms.

100-107. (canceled)

108. A chemical compound of the formula R1-R2-Si—(X1)3, wherein X1 is a halogen, acyloxy, alkoxy or OH group, R2 is an aromatic group having 8 carbon atoms and R1 is a substituent at position 5 of R2 selected from an alkyl group having from 1 to 4 carbon atoms, an alkenyl group having from 2 to 5 carbon atoms, an alkynyl group having from 2 to 5 carbon atoms, Cl or F.

109-112. (canceled)

113. A poly(organo siloxane) compound comprising a repeating Si—O backbone, carbon chain crosslinking groups and —R1-R2 bound to from 5% to 50% of the silicon atoms in the Si—O backbone, wherein R2 is an aromatic group having 8 carbon atoms and R1 is a substituent at position 5 of R2.

114-121. (canceled)

122. A poly(organo siloxane) compound comprising a repeating Si—O backbone, —R1-R2 bound to from 25% to 50% of the silicon atoms in the Si—O backbone, wherein R2 is an aromatic group having 8 carbon atoms and R1 is a substituent at position 5 of R2 (again this could be drawn out for clarity), and R3 bound to from 5% to 50% of the silicon atoms, wherein R3 is an alkenyl group having from 2 to 5 carbon atoms, acrylic group or epoxy group.

123-126. (canceled)

127. An integrated circuit having a layer with areas of an electrically conductive first material and an electrically insulating second material, wherein the second material is a poly(organo siloxane) compound comprising a repeating Si—O backbone, carbon chain crosslinking groups and —R1-R2 bound to from 5% to 50% of the silicon atoms in the Si—O backbone, wherein R2 is an aromatic group having 8 carbon atoms and R1 is a substituent at position 5 of R2.

128-133. (canceled)

134. A chemical compound of the formula R1-R2-Si—(X1)3, wherein X1 is a halogen, acyloxy, alkoxy or OH group, R2 is an aromatic group having 10 carbon atoms and R1 is a substituent at position 6 of R2 selected from an alkyl group having from 1 to 4 carbon atoms, an alkenyl group having from 2 to 5 carbon atoms, an alkynyl group having from 2 to 5 carbon atoms, Cl or F.

135-138. (canceled)

139. A poly(organo siloxane) compound comprising a repeating Si—O backbone, carbon chain crosslinking groups and —R1-R2 bound to from 5% to 50% of the silicon atoms in the Si—O backbone, wherein R2 is an aromatic group having 10 carbon atoms and R1 is a substituent at position 6 of R2.

140-147. (canceled)

148. A poly(organo siloxane) compound comprising a repeating Si—O backbone, —R1-R2 bound to from 25% to 50% of the silicon atoms in the Si—O backbone, wherein R2 is an aromatic group having 10 carbon atoms and R1 is a substituent at position 6 of R2, and R3 bound to from 5% to 50% of the silicon atoms, wherein R3 is an alkenyl group having from 2 to 5 carbon atoms, acrylic group or epoxy group.

149-152. (canceled)

153. An integrated circuit having a layer with areas of an electrically conductive first material and an electrically insulating second material, wherein the second material is a poly(organo siloxane) compound comprising a repeating Si—O backbone, carbon chain crosslinking groups and —R1-R2 bound to from 5% to 50% of the silicon atoms in the Si—O backbone, wherein R2 is an aromatic group having 10 carbon atoms and R1 is a substituent at position 6 of R2.

154-159. (canceled)

160. A method for making a chemical compound of the formula R1-R2-Si—(X1)3, wherein X1 is a halogen or alkoxy group, R2 is an aromatic group having 10 carbon atoms and R1 is a substituent at position 6 of R2, R1 being selected from an alkyl group having from 1 to 4 carbon atoms, an alkenyl group having from 2 to 5 carbon atoms, or OH, comprising:
reacting R1-R2-Br with Mg and Si—(OR3)4 to form R1-R2-Si—(OR3)3+BrMgOR, where R1 is selected from an alkyl group having from 1 to 4 carbon atoms, an alkenyl having from 2 to 5 carbon atoms, R2 is an aromatic or non-aromatic ring structure having from 5 to 7 carbon atoms, and R3 is an alkoxy group having from 1 to 3 carbon atoms;
reacting R1-R2-Si—(OR3)3 with 3 SO2Cl2 in the presence of C5H5N—HCl to yield R1-R2-SiCl3+3 SO2+3EtCl.

161-163. (canceled)

164. A thin film comprising a composition obtained by hydrolyzing
a monomeric silicon compound having at least one hydrocarbyl radical, containing an unsaturated carbon-to-carbon bond, and at least one hydrolyzable group attached to the silicon atom of the compound with
another monomeric silicon compound having at least one aryl group and at least one hydrolyzable group attached to the silicon atom of the compound
to form a siloxane material.

165-166. (canceled)
